(19) United States
(12) Patent Application Publication
(10) Pub. No.: US 2026/0221963 A1
(43) Pub. Date: Jul. 30, 2026

(54) POWER MANAGEMENT SYSTEMS AND CIRCUITRY

(71) Applicant: Arm Limited, Cambridge (GB)

(72) Inventors: Marlin Wayne FREDERICK, JR., Austin, TX (US); Andy Wangkun CHEN, Austin, TX (US); Vijaya Kumar VINUKONDA, Bangalore (IN); Ranabir DEY, Bangalore (IN); Edward Martin MCCOMBS, JR., Austin, TX (US)

(21) Appl. No.: 19/041,411

(22) Filed: Jan. 30, 2025

(51) Int. Cl. H03K 17/00; H03K 3/037; H03K 19/20

(52) U.S. Cl. CPC H03K 17/002; H03K 3/037; H03K 19/20

(57) ABSTRACT

Power multiplexer circuitry, systems, and methods. Power multiplexer circuitry includes interface control logic including first SR latch circuitry to generate first and second interface control signals responsive to first and second latch control signals, a PMUX control circuit to provide a first selection control signal responsive to the first interface control signal and to provide a second selection control signal responsive to the second interface control signal, a power output circuit to output a selected voltage at a PMUX output, the power output circuit including first switch circuitry arranged between a first voltage rail and the PMUX output to provide an electrical path therebetween responsive to the first selection control signal, and second switch circuitry arranged between a second voltage rail and the PMUX output to provide an electrical path therebetween responsive to the second selection control signal.

### TECHNICAL FIELD

Present techniques relate generally to power management in an integrated circuit device(s).

### BACKGROUND

Integrated circuit (IC) devices include processing components such as a central processing unit (CPU), a graphics processing unit (GPU) as well as processing components optimised for neural networks used in machine learning and artificial intelligence applications. Applications of these processing components are many and varied and include general purpose computing applications as well as use in smartphones, personal computer and mobile gaming, embedded systems, autonomous vehicles, data centres and high-performance computing.

Depending on the deployed architecture and application, processors can vary greatly in terms of performance, power consumption and scalability.

### SUMMARY

The present technology is directed to a method and circuit for improved power management. The present technology may be applicable for multicore systems having multiple power domains.

In a first aspect there is provided power multiplexer circuitry comprising: interface control logic comprising: first SR latch circuitry to generate first and second interface control signals responsive to first and second latch control signals; a PMUX control circuit to provide a first selection control signal responsive to the first interface control signal and to provide a second selection control signal responsive to the second interface control signal; a power output circuit to output a selected voltage at a PMUX output, the power output circuit comprising: first switch circuitry arranged between a first voltage rail and the PMUX output to provide an electrical path therebetween responsive to the first selection control signal; second switch circuitry arranged between a second voltage rail and the PMUX output to provide an electrical path therebetween responsive to the second selection control signal.

In a further aspect there is provided a system comprising power multiplexer circuitry comprising: interface control logic comprising: SR latch circuitry to generate first and second interface control signals responsive to first and second latch control signals; a PMUX control circuit to provide a first selection control signal responsive to the first interface control signal and to provide a second selection control signal responsive to the second interface control signal; a power output circuit to output a selected voltage at a PMUX output, the power output circuit comprising: first switch circuitry arranged between a first voltage rail and the PMUX output to provide an electrical path therebetween responsive to the first selection control signal; second switch circuitry arranged between a second voltage rail and the PMUX output to provide an electrical path therebetween responsive to the second selection control signal.

In a further aspect there is provided non-transitory computer-readable medium to store computer-readable code for fabrication of the circuitry of the above circuit.

In a further aspect there is provided a system comprising: the circuitry of the above circuit, implemented in at least one packaged chip; at least one system component; and a board, wherein the at least one packaged chip and the at least one system component are assembled on the board.

In a further aspect there is provided a chip-containing product comprising the system of the previous aspect assembled on a further board with at least one other product component.

### BRIEF DESCRIPTION OF THE DRAWINGS

Implementations of the disclosed technology will now be described, by way of example only, with reference to the accompanying drawings, in which:

FIG. 1a shows an example of a system having PMUX modules to supply storage circuitry;

FIG. 1b shows an example waveform depicting the operation of the PMUX modules of FIG. 1a in accordance with the present techniques;

FIG. 2 shows an example system comprising a power multiplexer module in accordance with the present techniques;

FIG. 3 shows a further example system comprising a power multiplexer module in accordance with the present techniques;

FIG. 4 shows a further example system comprising a power multiplexer module in accordance with the present techniques;

FIG. 5 shows a further example system comprising a power multiplexer module in accordance with the present techniques;

FIG. 6 shows a further example system comprising a power multiplexer module in accordance with the present techniques;

FIG. 7 shows a further example system comprising a power multiplexer module in accordance with the present techniques;

FIG. 8 shows a further example system comprising a power multiplexer module in accordance with the present techniques;

FIG. 9 shows a further example system comprising a power multiplexer module in accordance with the present techniques;

FIG. 10 is a flow diagram for providing selector circuitry in accordance with the present techniques;

FIG. 11 shows a system and a chip-containing product in accordance with the present techniques.

### DETAILED DESCRIPTION

Various implementations described herein are directed to power management in integrated circuit (IC) systems.

Typical integrated circuit systems comprise one or more subsystems, such as a central processor unit (CPU), graphics processor unit (GPU), where each subsystem may have associated storage (or memory) circuitry, such as random access memory (RAM) (e.g. static RAM (SRAM)).

Such storage circuitry may include one or more storage cells (hereafter “bitcells”) arranged in one or more arrays (hereafter “bitcell arrays”). The bitcells may be arranged in rows and columns in the bitcell arrays, where individual bitcells in the rows may be addressed/selected via respective wordlines and individual bitcells in each column may be addressed/selected via respective bitlines. The storage cells may be supplied by a first voltage at a first voltage level, which is hereafter referred to as a “cell voltage level” or “VDDCE”.

The storage circuitry may have associated peripheral circuitry to address/select individual bitcells via the wordlines and bitlines (to write to and read from the individual bitcells and to sense data stored in the bitcells via the wordlines and bitlines). The peripheral circuitry may be supplied by a second voltage at a second voltage level, which is hereafter referred to as a “peripheral voltage level” or “VDDPE”.

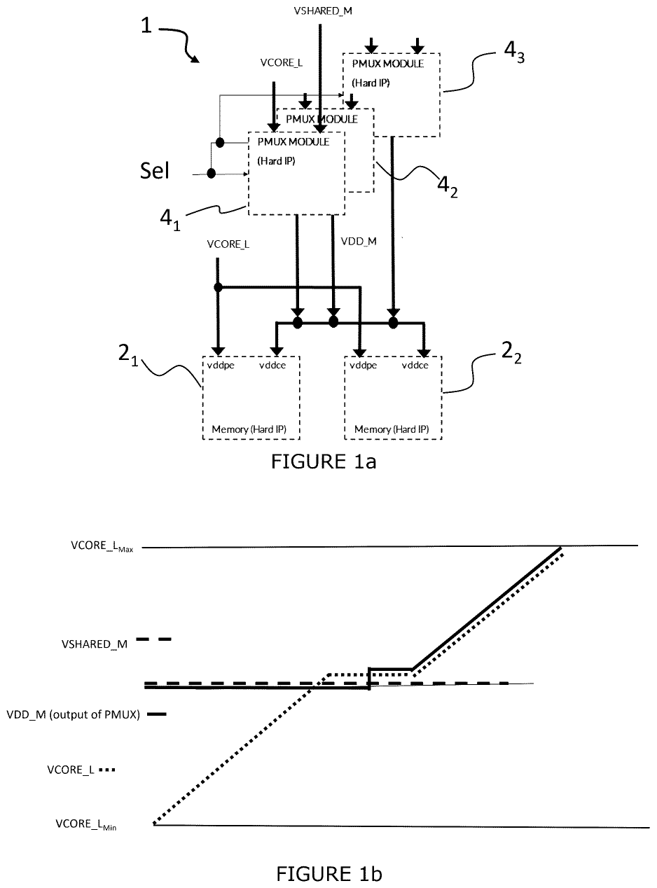

As depicted in FIG. 1a, a system 1 may comprise multiple storage circuits 2ₙ (two of which are depicted in FIG. 1), each comprising cell circuitry (not shown) supplied with a first voltage (VDD_M) via a vddce input and peripheral circuitry (not shown) supplied with a second voltage (VDDPE) via a vddpe input.

One or more power multiplexer (PMUX) modules 4ₘ (three of which are depicted in FIG. 1a) may be arranged to supply VDD_M to the cell circuitry of the respective storage circuits.

Each PMUX module 4ₘ receives a first voltage VDD0 (e.g. a nominal voltage (VSHARED_M)) and a second VDD1 (e.g. VCORE_L) and controls the PMUX Output (e.g. VDD_M) to substantially track VDD0 or VDD1.

A selection control signal (Sel), which may be provided by firmware may be used to control the PMUX modules to select VDD_M to substantially track one of VSHARED_M or VCORE_L.

The storage cells 2ₙ may have a minimum operating voltage (e.g. as specified by a foundry or by design). In the present illustrative examples, the nominal voltage (VSHARED_M) is set at the minimum operating voltage of the storage cells, which is taken to be 0.75v.

The peripheral circuitry may be capable of operating at a lower voltage than the minimum operating voltage of the storage cells. In the present illustrative example, the core voltage (VCORE_L) may be supplied in the operational range of the peripheral circuitry (e.g. from VCORE_L_{Min}=0.55v to VCORE_L_{Max}=0.95v). VCORE_L may be adjusted for, for example, dynamic voltage and scaling (DVFS) sequence operations, where operating with VCORE_L below the nominal voltage (VSHARED_M) may improve power efficiency but may negatively affect performance, whereas operating with VCORE_L above the nominal voltage may improve performance but reduce power efficiency.

When the level of voltage VCORE_L supplied to the peripheral circuitry is greater than the nominal voltage (VSHARED_M), the cell circuitry should be supplied with VDD_M (VDDCE) that substantially tracks (or is substantially equal to) VCORE_L or system performance may be affected (E.g. due to timing issues, read and/or write stability issues).

FIG. 1b shows an illustrative waveform depicting the voltage inputs (VCORE_L and VSHARED_M) to a PMUX module and the PMUX output (VDD_M) from the PMUX module to supply voltage VDDCE to the cell circuitry. As depicted in FIG. 1b, when VCORE_L ≤VSHARED_M, the output VDD_M of the PMUX modules 4m should track VSHARED_M, and when VCORE_L>VSHARED_M, the output VDD_M of the PMUX modules 4m should track VCORE_L.

A system control processor (SCP) may communicate with the PMUX modules to instruct/control the PMUX module(s) to output VDD_M to track VSHARED_M or VCORE_L, via one or more selection signals (SEL0 or SEL1).

The SCP may communicate with a power management integrated circuit (PMIC) to control the level of VCORE_L and software (SW) (e.g. firmware (FW)) and/or hardware (HW) may be provided to monitor or sense the level of VCORE_L relative to VSHARED_M, where, for example, signal SEL0 may be provided to cause VDD_M to track VSHARED_M (i.e. to cause the PMUX module to select VSHARED_M) and SEL1 may be provided to cause VDD_M to track VCORE_L (i.e. to cause the PMUX module to select VCORE_L). Such sensing may be done, for example using a delay monitor or internal timer based on programmable ramp-up rate of the PMIC.

As an illustrative example depicted in FIG. 1b, it may be desired for VCORE_L to be increased from VCORE_LMin to VCORE_LMax (e.g. during a DVFS sequence). In operation, the SCP may first request the PMIC to raise VCORE_L to the same level as VSHARED_M, where SEL0 is provided to select VDD_M to track VSHARED_M while VCORE_L<VSHARED_M.

When it is determined that VCORE_L is stable at the same level as VSHARED_M, the SCP may then request that the PMIC raise VCORE_L to VCORE_LMax, and instruct/control the PMUX module(s), via one or more selection signals (SEL1), to select VDD_M to substantially track VCORE_L.

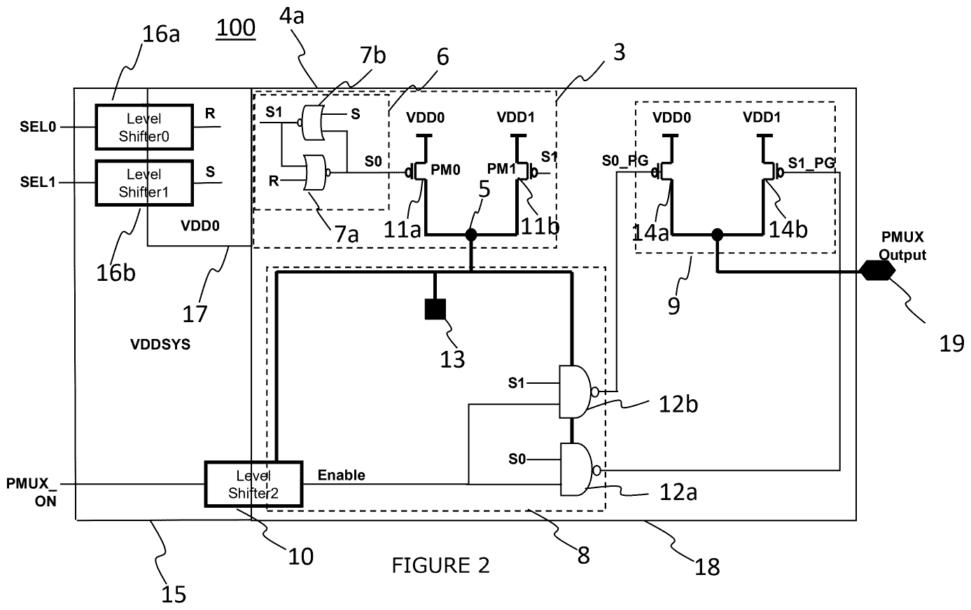

FIG. 2 illustratively shows an example system 100 showing a logic implementation of a PMUX module 4a in accordance with the present techniques.

It will be appreciated that the term “signal” is non-limiting and may take any form to convey a message, operation or information to a component (hardware or software), where, for example, the signal may comprise one or more bits, a logic value (e.g. high or low), or a voltage value etc. In embodiments the signal may comprise a clock signal having a particular frequency and or level (e.g. voltage level). Furthermore, the signals provided to a component (e.g. hardware or software) to control the operation thereof (E.g. to select a particular clock signal) or to change properties thereof (e.g. to cause the component to operate in a certain way) may be referred to as a “control signal.”

The PMUX module 4a comprises an interface circuit 3, to provide a voltage at interface output node 5.

The interface circuit comprises interface control logic 6, which in FIG. 2 is depicted as an SR latch comprising logic gates 7a and 7b, where the SR latch 6 is to generate interface control signals (S0 and S1) responsive to control signals R and S. In the examples herein, the logic gates 7a/b comprise NOR gates, although any logic gates (or combination thereof) may be used in accordance with the present techniques.

The interface control signals S0/S1 are provided to control interface switch circuitry. In the present illustrative examples the interface switch circuitry comprises one or more transistors although any components may be used to provide the switching functionality in accordance with the present techniques.

In the illustrative examples, the interface control signal S0 is provided to the gate of PMOS interface transistor PM0 11a to control the functionality (or state thereof) e.g. to turn the interface transistor on or off. Interface control signal S1 is provided to the gate of PMOS interface transistor PM1 11b to control the functionality thereof (or state thereof).

When activated (turned on) responsive to interface control signal S0=0 (or LOW), the PMOS transistor PM0 provides an electrical path between first voltage rail comprising VDD0 and the interface output node 5. Similarly, when activated (turned on) responsive to interface control signal S1=0 (or LOW), the PMOS transistor PM1 provides an electrical path between a second voltage rail comprising VDD1 and interface output node 5.

In the present illustrative example, the interface output node 5 is in electrical communication with well tap 13 which is to power the source of the NWell of the PMUX module 4a, and to various circuitry (e.g. level shifter 10 and logic gates 12a/b). Thus, in the present illustrative example, the PMUX module comprises a third voltage domain 18, which is powered by the selected voltage VDD0 or VDD1.

As described above, the PMUX module 4a is to, responsive to external control signals (e.g. SEL0/SEL1), select the PMUX output (VDD_M) to be the higher of a first voltage VDD0 or a second voltage VDD1 (e.g. for a DVFS operation).

Selection input signals (e.g. first selection signal SEL0 & second selection signal SEL1) may be provided (e.g. by firmware) to select VDD0 or VDD1 when switching is required.

The external first selection signal (SEL0) and second external selection signal (SEL1) are in a first voltage domain 15 (e.g. VSYS) and are level shifted, using level shifters 16a/16b, from the first voltage domain (e.g. VSYS) to a second voltage domain 17 (e.g. VDD0), to provide internal latch control signals R and S for the SR latch 6. It is known to provide a voltage level shifter to convert a signal from one voltage domain to a signal suitable for another voltage domain (e.g. VSYS to VDD0 or VDD0 to VDD1). This allows circuits that operate different voltage levels to interface with each other.

An example voltage domain or voltage rail power up sequence for powering the system 100 comprises: VDDSYS->VDD0->VDD1, where, as the voltage is ramped up, the VDDSYS power domain will power up first, followed by the VDD0 power domain, followed by VDD1 domain. When ramping down, the sequence will flow from VDD1, to VDD0 to VDDSYS.

In the present illustrative example, in operation, when VDD0 is required as VDDCE, the first external selection signal SEL0 is provided to cause the PMUX module to select VDD0, where when SEL0=1 (HIGH) then SEL1=0 (LOW), R=1, and S=0. When R=1, and S=0 then S0=0 and S1=1. When interface control signal S0 is 0 (or low) PM0 is turned on (and PM1 is turned off) and VDD0 is supplied from the interface circuit 3 to PMUX control circuit 8.

When, e.g. due to a DVFS operation, VDD1 is required, external second selection signal SEL1 is provided to cause the PMUX module 4a to select VDD1, where when SEL0=0 then SEL1=1, R=0, and S=1. When R=0, and S=1 then S0=1 and S1=0. When interface control signal S1 is 0 (or low) PM1 is turned on (and PM0 is turned off) and VDD1 is supplied from the interface circuitry 3 to PMUX control circuit 8.

When switching is not required then external selection signals may both be set to be zero (e.g. SEL0=SEL1=0), such that in the present illustrative example S=R=0, and the SR latch 6 would be a cross-loop back latch.

An SR latch is beneficial as there is no leakage path in an SR latch when S=R=0. Furthermore, as the SR latch is toggled when VDD0≈VDD1, the risk of a leakage path forming in the SR latch is reduced. Furthermore still, the interface control signals can be produced by the SR latch without a DC path.

PMUX control circuit 8 comprises first logic gate 12a which is to receive first interface control signal S0 from SR latch 6 as a first input thereto and an enable signal as a second input thereto, and where the logic gate 12a is to generate a first selection control signal (S0_PG) responsive to the interface control signal S0 and the enable signal.

PMUX control circuit 8 also comprises second logic gate 12b which is to receive second interface control signal S1 from SR latch 6 as a first input thereto, and the enable signal as a second input thereto, and where the logic gate 12b is to generate a second selection control signal (S1_PG) responsive to the interface control signal S1 and the enable signal.

In the examples herein, the logic gates 12a/b comprise NAND gates although any logic gates (or combination thereof) may be used in accordance with the present techniques.

The PMUX module 4a also comprises a power output circuit 9 to output the selected voltage via PMUX output 19.

The power output circuit 9 comprises a first power gate (or select) transistor 14a arranged between first voltage rail VDD0 and the PMUX output 19 and a second power gate (or select) transistor 14b arranged between second voltage rail VDD1 and the PMUX output 19.

The selection control signal (S0_PG) from the first NAND gate 12a is provided to the first power gate (or select) transistor 14a and the selection control signal (S1_PG) from the second NAND gate 12b is provided to the gate of second power gate (or select) transistor 14b. In the illustrative example the first and second power gate (or select) transistors 14a/b comprise PMOS transistors.

A level shifter 10, powered by the selected voltage (VDD0 or VDD1), is to level shift a PMUX enable signal (PMUX_ON) from the first voltage domain 15 to the voltage level of the third voltage domain 18 (VDD0 or VDD1).

When activated (turned on) responsive to selection control signal S0_PG=0 (or LOW), the first power gate (or select) transistor 14a provides an electrical path between the first voltage rail comprising VDD0 and the PMUX output 19. Similarly, when activated (turned on) responsive to selection control signal S1_PG=0 (or LOW), the second power gate (or select) transistor 14b provides an electrical path between the second voltage rail comprising VDD1 and the PMUX output 19. As above, the PMUX output 19 is, for example, supplied as VDDCE to cell circuitry.

Thus, the present techniques provide a PMUX module 4a having interface circuitry comprising an SR latch which can be used to, responsive to external selection control signals (SEL0 or SEL1), select a first voltage or second voltage as an output voltage (e.g. VDD_M) to be supplied to cell circuitry of a storage system (e.g. SRAM)

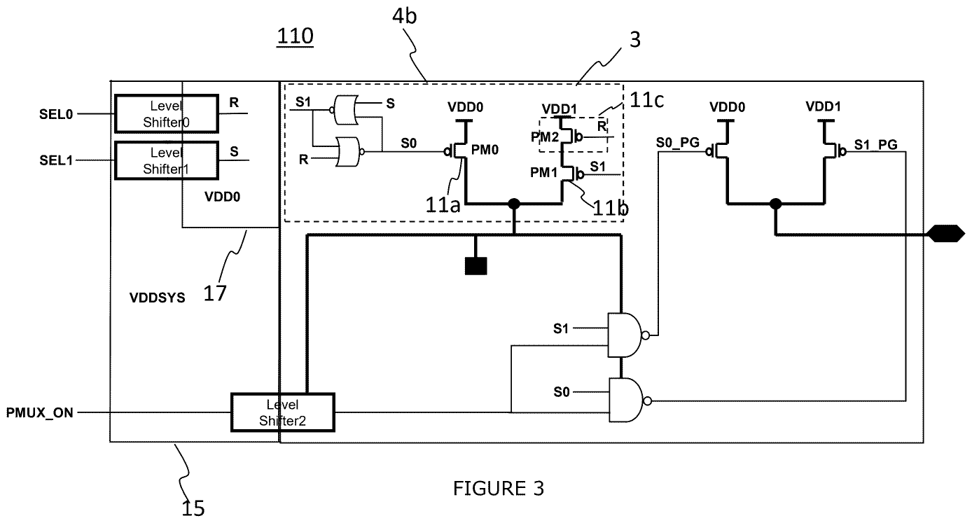

FIG. 3 illustratively shows an example system 110 showing a logic implementation of a PMUX module 4b in accordance a further embodiment of the present techniques.

The example system 110 is similar to system 100 depicted in FIG. 2, where the interface circuit 3 further comprises an additional transistor 11c in series between the voltage rail VDD1 and the transistor PM1 11b.

As above, an example voltage domain or voltage rail power up sequence for powering a system comprises: VDDSYS->VDD0->VDD1, where as the voltage is ramped up, the VDDSYS power domain will power up first, followed by the VDD0 power domain, followed by VDD1 domain. When ramping down, the sequence will flow from VDD1, to VDD0 to VDDSYS.

During the ramp up sequence, the voltage domain VDD0 will be powered before VDD1 such that when VDD0 is required, the first external selection signal SEL0=1 is provided to select VDD0 (and SEL1=0 (LOW), R=1, and S=0 and S0=0). Thus, interface control signal S0 is 0 (or low) such that PMOS transistor PM0 11a is turned on and VDD0 is supplied to PMUX control circuit 8, whilst PMOS transistor PM1 11b is turned off responsive to S1=1 and additional PMOS transistor PM2 11c is turned off responsive to latch control signal “R=1,”

The interface control signal S1 signal is generated in the third voltage domain 18, so the assertion of interface control signal S1 to control PM1 to be OFF may be delayed until the third power domain is powered up sufficiently. The latch control signal R is generated in the second voltage domain 17, and therefore controlling the additional transistor PM2 11c responsive to the latch control signal “R”, which is generated in the second voltage domain, means that, when ramping up from VSYS to VDD0, the additional transistor PM2 11c will be powered off when the first power domain VDD0 is selected (responsive to SEL0=0) thereby preventing any leakage path which may result from waiting for the PM1 to be turned off responsive to interface control signal S1 alone.

Furthermore, when VDD1 is required, the second external selection signal SEL1=1 is provided to select VDD1 (and SEL0=0, R=0, S=1 and S1=0). Thus, R=0 and S1=0 such that PMOS transistors PM1 11b and PM2 11c are turned on and S0=1 such that PMOS transistor PM0 11a is turned off, thereby supplying VDD1 from the interface circuit 3 to node 5.

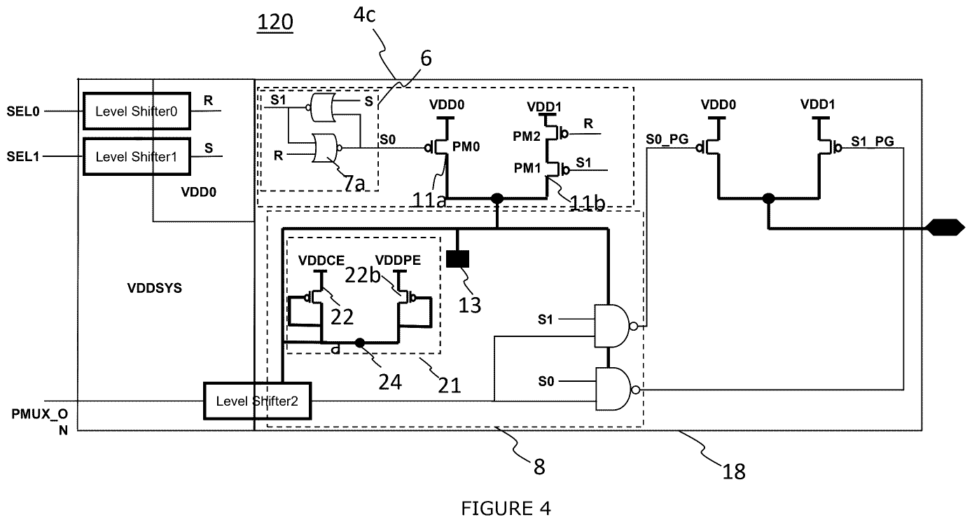

FIG. 4 illustratively shows an example system 120 showing a logic implementation of a PMUX module 4c in accordance a further embodiment of the present techniques.

The example system 120 in FIG. 4 is similar to system 100 depicted in FIG. 2 and system 110 depicted in FIG. 3, where the PMUX control circuit 8 further comprises clamp circuitry 21 to further achieve a reliable ramp-up sequence.

As depicted in FIG. 4, the clamp circuitry 21 comprises PMOS transistors 22a/22b arranged as a diode clamp, where transistor 22a is arranged between voltage rail VDDCE and node 24 and the transistor 22b is arranged between voltage rail VDDPE and node 24. Node 24 is in electrical communication with the level shifter 10 and the well tap 13 of the third voltage domain 18.

As described in the systems depicted in FIGS. 2 and 3 above, during ramp up sequence, SEL0 is selected (i.e. SEL0=1) when VDD0 is required. Thus, when SEL0=1, then R=1 and S0=0 to enable PMOS transistor PM0, where the well tap 13 of the third voltage domain is powered using VDD0.

When VDD0 is ramping up, as the SR latch 6 is in the third domain 18, interface control signal S0 may not be sufficiently low (or at 0) to turn on the PMOS transistor PM0 11a (i.e. due to the voltage threshold Vt of PM0 11a).

Initially, before VDD0 ramps up VDD0=0 so the input to the gate of PMOS transistor 22a is 0, and therefore the PMOS transistor 22a is enabled, which in turn powers the third domain using VDDCE. Thus, the NOR gate 7a of the SR latch 6 which is in the third voltage domain is enabled and asserts S0=0 to turn on PM0.

Thus, providing the clamp circuitry 21 ensures that the output from the SR latch circuitry 6 is, at the beginning of the ramp-up sequence to VDD0, sufficient to overcome the voltage threshold (Vt) of transistor PM0 to turn on transistor PM0 and provide an electrical path between the VDD0 rail and the PMUX control circuit 8.

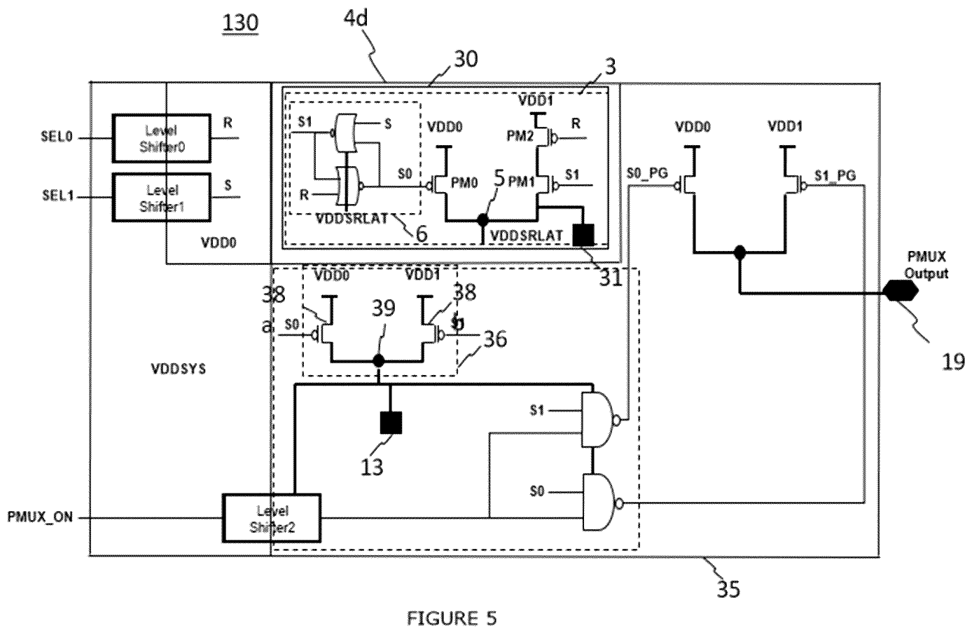

FIG. 5 illustratively shows an example system 130 showing a logic implementation of a PMUX module 4d in accordance a further embodiment of the present techniques.

The example system 130 in FIG. 5 is similar to system 100 depicted in FIG. 2 and system 110 depicted in FIG. 3.

In the illustrative example in FIG. 5, the interface circuit 3 is provided in a voltage domain 30, where a well tap 31 of the voltage domain 30 is in electrical communication with the interface output node 5 to power the voltage domain 30 using the selected voltage (e.g. VDD0 or VDD1).

The PMUX control circuit 8 and power output circuit 9 are provided in a further voltage domain 35, where the voltage domain 30 is electrically isolated from the further voltage domain 35. The isolation may be provided by a physical separation (e.g. by providing the domains in different wells (E.g. NWell) or by providing an insulative material between the domains 30/35.

The output from the node 5 (depicted as VDDSRLAT) is used to power the voltage domain (via well tap 31) and the interface control logic 6.

The PMUX control unit 8 is provided with a further voltage supply circuit 36 comprising a first transistor 38a arranged between first voltage rail VDD0 and the node 39 and a second transistor 38b arranged between second voltage rail VDD1 and node 39.

The further voltage supply circuit 36 is arranged to supply the selected voltage (VDD0 or VDD1) to the well tap 13, and to various circuitry of the PMUX control unit 8 (e.g. level shifter 10 and NAND gates 12a/b).

The first interface control signal (S0) from the SR latch 6 is provided to the first transistor 38a and the second interface control signal (S1) from the SR latch 6 is provided to the gate of second transistor 38b. In the illustrative example the transistors 38a/b of the further voltage supply circuit 36 comprise PMOS transistors.

Thus, when activated (turned on) responsive to first interface control signal S0=0 (or LOW), the PMOS transistor 38a provides an electrical path between the first voltage rail (VDD0) and the well tap 13 and when activated (turned on) responsive to second interface control signal S1=0 (or LOW) the PMOS transistor 38b provides an electrical path between the second voltage rail (VDD1) and the well tap 13.

Providing electrical isolation between the voltage domain 30 and voltage domain 35 provides for a reduced capacitance at the output of the interface control logic 6 such that the voltage domain 30 will power up with VDD0 sooner compared to the systems depicted in FIGS. 2-4 above. This provides for improved and more accurate operation of the PMUX module and reduces the risk of an incorrectly selected voltage being output at the PMUX output 19.

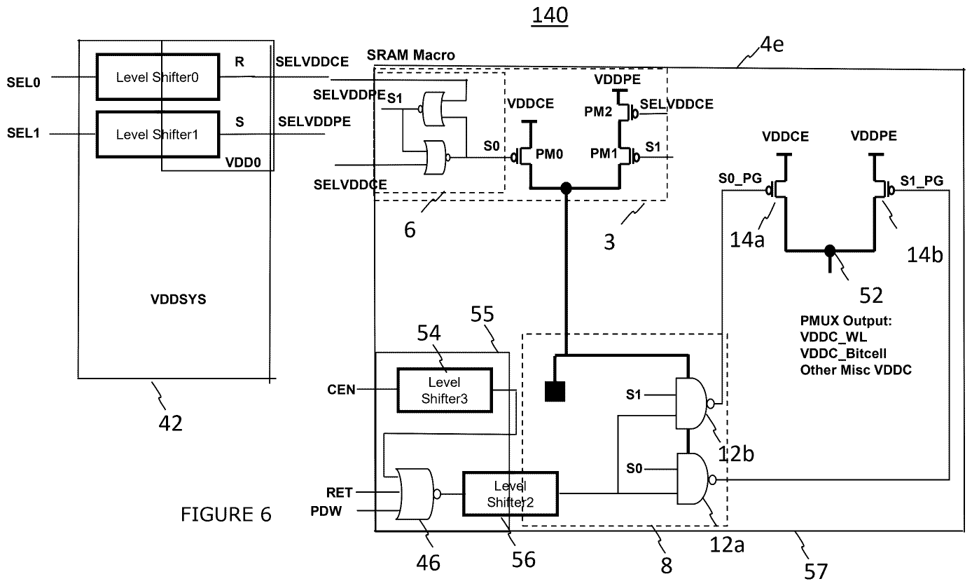

FIG. 6 illustratively shows an example storage system 140 showing a logic implementation of a PMUX module 4e in accordance a further embodiment of the present techniques.

The system 140 in FIG. 6 is similar to system 100 depicted in FIG. 2 and system 110 depicted in FIG. 3 although in the illustrative example of FIG. 6, the PMUX module 4e is integrated into a storage system (e.g. integrated in static random access memory circuitry), and receives signals from the storage system. Furthermore, the voltage rails are internal to the storage system (e.g. depicted as VDDCE and VDDPE).

In the PMUX module 4e depicted in FIG. 6, the interface control logic 6 receives internal latch control signals SELVDDCE and SELVDDPE, which may be provided from a Power Module Unit 42, which may be part of the storage system (e.g. SRAM).

First latch Control signal SELVDDCE is a first input to the interface control logic 6 and second latch control signal SELVDDPE is a second input to the interface control logic 6. In operation, first external control signal SEL0, in a first voltage domain (VDDSYS), is level shifted, using “Level Shifter0”, to latch control signal SELVDDCE in a second voltage domain (VDD0). The level shifter may be provided internal to the storage system 140.

Furthermore, second external control signal SEL1, in the first voltage domain (VDDSYS), is level shifted, using “Level Shifter1” to latch control signal SELVDDPE in the second voltage domain (VDD0).

The PMUX module 4e receives an enable signal (Chip Enable (CEN)) (e.g. from the storage system in which it's integrated, which is at the voltage level VDDPE.

The CEN signal is, using level shifter 54, level shifted to voltage level VDDCE, and provided as a first input to logic gate 46, which is in a further voltage domain 55. In the examples herein, the logic gate 46 comprises a NOR gate although any logic gates (or combination thereof) may be used in accordance with the present techniques.

NOR gate 46 also receives retention signal (RET) and power down signal (PDW) from the storage circuit in which it's integrated, where the retention signal (RET) and power down signal (PDW) are all at the voltage level of the voltage domain 55 in which the NOR gate 46 is located.

The output from the NOR gate 46, which is at the voltage level of the voltage domain 55, is, using level shifter 56, level shifted to the selected voltage (VDDCE or VDDPE) in voltage domain 57 and provided as an enable signal to the PMUX control circuit 8.

As above, PMUX control circuit 8 comprises first NAND gate 12a which is to receive first interface control signal S0 from the SR latch 6 as a first input thereto and the enable signal from level shifter 56 as a second input thereto.

PMUX control circuit 8 also comprises second NAND gate 12b which is to receive second interface control signal S1 from the SR latch 6 as a first input thereto and the enable signal from level shifter 56 as a second input thereto.

The selection control signal (S0_PG) from the first NAND gate 12a is provided to the gate of first power gate (or select) transistor 14a and the selection control signal (S1_PG) output from the second NAND gate 12b is provided to the gate of second power gate (or select) transistor 14b. In the illustrative example the first and second power gate transistors comprise PMOS transistors.

When activated (turned on) responsive to selection control signal S0_PG=0 (or LOW), the first power gate (or select) transistor 14a provides an electrical path between the first voltage rail comprising VDDCE and the PMUX output 52. Similarly, when activated (turned on) responsive to selection control signal S1_PG=0 (or LOW), the second power gate (or select) transistor 14b provides an electrical path between the second voltage rail comprising VDDPE and the PMUX output 52. The PMUX output 52 is, for example, supplied as VDDCE to cell circuitry (e.g. wordlines, bitcells and other cell circuitry).

Thus, the present techniques provide a PMUX module 4e integrated in a storage system (e.g. in SRAM), where the PMUX module 4e, which comprises interface circuitry comprising an SR latch, may, responsive to selection signals from the storage system, select a first voltage (e.g. VDDCE) or second voltage (e.g. VDDPE) as an output to cell circuitry of the storage system.

Similar techniques to achieve reliable operation of the circuitry (e.g. transistors, logic gates etc.), such as those techniques described above in FIGS. 3-5 above may be applied to an integrated PMUX circuit.

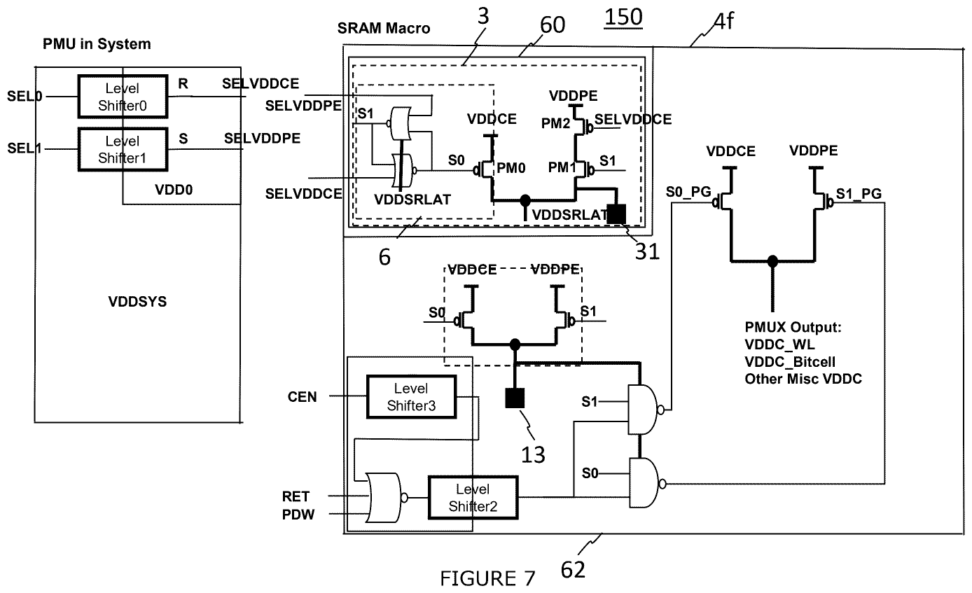

In an illustrative example, FIG. 7 shows an example storage system 150 showing a logic implementation of an integrated PMUX module 4f in accordance a further embodiment of the present techniques.

The example system 150 in FIG. 7 is similar to the storage system 140 depicted in FIG. 6, where the interface circuit 3 is provided in a first voltage domain 60 and PMUX control circuit 8 is provided in a second voltage domain 62, where the first voltage domain 60 is electrically isolated from the second voltage domain 62. Such electrical isolation may be obtained by a physical separation, or a material separation (e.g. providing insulative material therebetween).

The output from the interface circuit 3 is used to power the interface control logic 6 (depicted as VDDSRLAT) and the well tap 31.

As above in the system of FIG. 5, the PMUX control circuit 8 is provided with a voltage supply circuit 36 arranged to supply VDDCE or VDDPE to the well tap 13 to power the second voltage domain 62.

Providing electrical isolation between the first voltage domain 60 and second voltage domain 62 in the integrated PMUX module 4f provides for a reduced capacitance at the output of the interface control logic 6 such that the first voltage domain 60 will power up with VDDCE sooner compared to the system depicted in FIG. 6 above.

Providing the electrical isolation is only one example of an enhancement or improvement that may be made to a system in accordance with the present techniques.

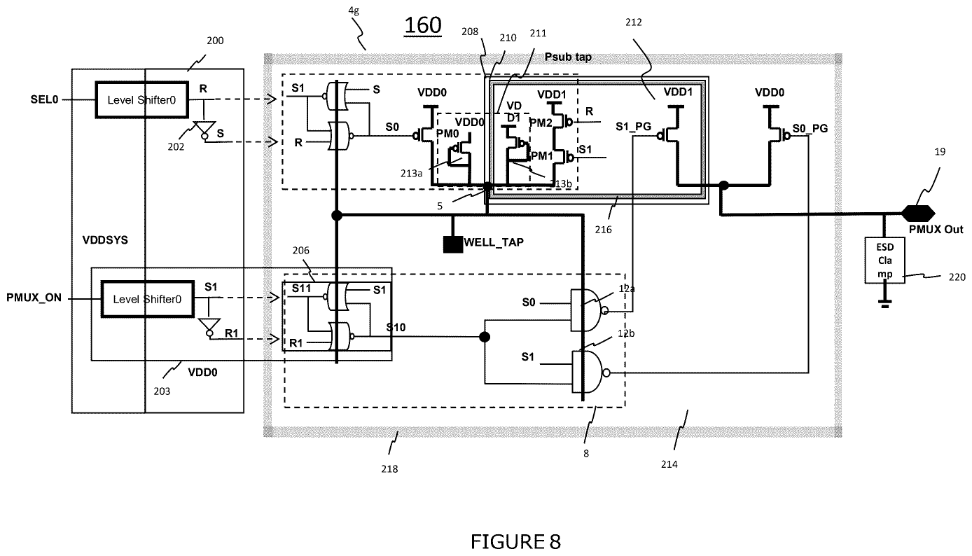

FIG. 8 shows a system 160 comprising PMUX module 4g having various improvements or enhancements made thereto, of which one or more of the improvements or enhancements may be applied to the systems depicted in FIGS. 2 to 7.

An example improvement or enhancement is depicted at 200, where to reduce the amount of components in the system one or more of the level shifters (e.g. the level shifter to level shift SEL1 from VDDSYS to VDD0) may be removed, where the output from the level shifter used to level shift SEL0 from VDDSYS to VDD0 may be inverted using inverter 202. Thus, the system only requires one input pin (SEL0) and one level shifter (Level Shifter0) to provide the “R” and “S” inputs to the SR latch rather than two pins and two level shifters.

A further example of an improvement or enhancement is depicted at 203, where rather than using a level shifter to provide the enable signal (depicted as S10) to the NAND gates 12a/b of the PMUX control circuit 8, the PMUX control circuit 8 comprises an SR latch 206 to provide the enable signal S10. Using the SR latch means that the enable signal S10 and be generated without a DC path as would otherwise be required when using a level shifter.

The latch control signals S1 and R1 for the SR latch 206 can be output from individual level shifters, or as depicted in FIG. 8, a single latch control signal S1 can be inverted to provide latch control signal R1 to reduce the amount of circuitry required to generate the signals.

A further example of an improvement or enhancement is depicted at 208, where an electrical separation (e.g. physical separation or insulative material) is provided to electrically isolate the VDD0 rail (in NWell 214) and VDD1 rail (in NWell 212) of the PMUX module 4. Providing the electrical separation increases the resistance between the VDD0 and VDD1 rails and reduces the opportunity for a leakage path to develop between the VDD0 and VDD1 rails. Put another way, electrical separation of the VDD0 and VDD1 rails weakens the conditions for an electrical discharge path (ESD) to develop between VDD1 and VDD0.

When an electrical separation is provided between the rails, clamp circuitry 211 may be provided in the interface circuit 3. As illustratively shown in FIG. 8, clamp circuitry 211 comprises PMOS transistors 213a/213b arranged as a diode clamp, where transistor 213a is arranged between voltage rail VDD0 and output node 5 in the first NW 214 and transistor 213b is arranged between voltage rail VDD1 and the interface output node 5 in the NWell 212.

A further example of an improvement or enhancement is shown in FIG. 8 where a first P-substrate tap (Ptap) 216 is provided around the NWell 212 and a second Ptap 218 is provided around the NWell 214. The Ptaps 216/218 reduce substrate resistance during a latch operation, and may avoid erroneous switching of transistor states e.g. the Ptaps 216/218 may maintain a transistor to be turned on or turned off as required and prevent a transistor incorrectly switching states.

A further example of an improvement or enhancement is shown in FIG. 8 where an ESD clamp 220 is provided on the electrical path between the PMUX output 19 and the cell circuitry of the storage system to reduce the effects of ESD.

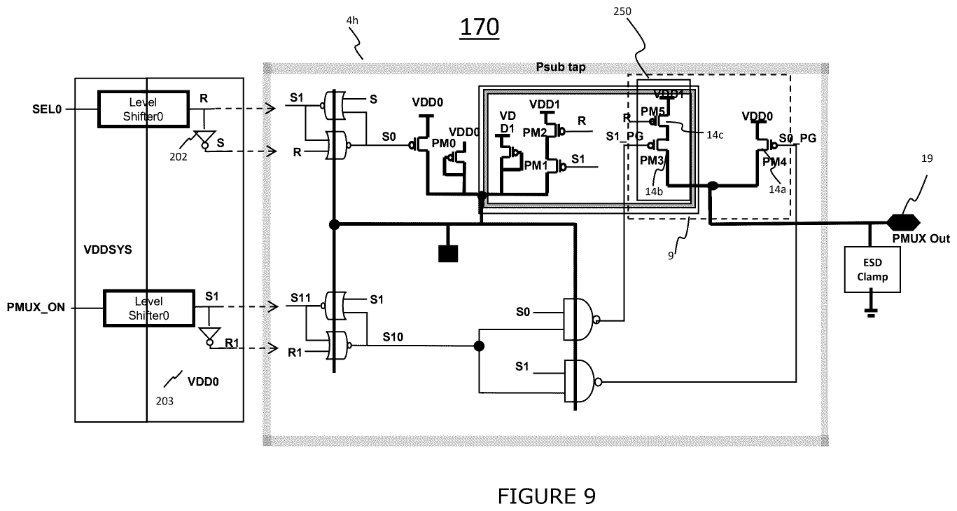

FIG. 9 shows a system 170 comprising PMUX module 4h having an improvement or enhancement made thereto depicted at 250 which may be applied to the systems depicted in FIGS. 2 to 8.

In accordance with the improvement, the power output circuit 9 further comprises an additional transistor 14c in series between the voltage rail VDD1 and the second power gate (or select) transistor 14b.

As above, an example voltage domain or voltage rail power up sequence for powering a system comprises: VDDSYS->VDD0->VDD1, where, as the voltage is ramped up, the VDDSYS power domain will power up first, followed by the VDD0 power domain, followed by VDD1 domain. When ramping down, the sequence will flow from VDD1, to VDD0 to VDDSYS.

As described above in FIG. 2, the power output circuit 9 comprises the first power gate (or select) transistor 14a arranged between first voltage rail VDD0 and the PMUX output 19 and the second power gate (or select) transistor 14b arranged between second voltage rail VDD1 and the PMUX output 19. In accordance with the improvement 250, an additional third power gate (or select) transistor 14c is provided in series between the voltage rail VDD1 and the second power gate (or select) transistor 14b.

As described above, the selection control signal (S0_PG) from the first NAND gate 12a is provided to the first power gate (or select) transistor 14a and the selection control signal (S1_PG) from the second NAND gate 12b is provided to the gate of second power gate (or select) transistor 14b. In the system 270 the third power gate (or select transistor) is controlled responsive to latch control signal “R”.

In the illustrative example the first, second and third power gate (or select) transistors 14a/b/c comprise PMOS transistors.

As also described above, when activated (turned on) responsive to selection control signal S0_PG=0 (or LOW), the first power gate (or select) transistor 14a provides an electrical path between the first voltage rail comprising VDD0 and the PMUX output 19. Similarly, when activated (turned on) responsive to selection control signal S1_PG=0 (or LOW), the second power gate (or select) transistor 14b provides an electrical path between the second voltage rail comprising VDD1 and the PMUX output 19.

An example voltage domain or voltage rail power up sequence for powering a system comprises: VDDSYS->VDD0->VDD1, whereas the voltage is ramped up, the VDDSYS power domain will power up first, followed by the VDD0 power domain, followed by VDD1 domain. When ramping down, the sequence will flow from VDD1, to VDD0 to VDDSYS.

During the ramp up sequence, the voltage domain VDD0 will be powered before VDD1 such that when VDD0 is required, the first external selection signal SEL0=1 is provided to select VDD0 (and R=1, and S=0 and S0=0). Thus, control signal S0 is 0 (or low) and S1 is 1 (or HIGH) such that power gate (or select) transistor 14a is turned on and VDD0 is supplied to PMUX output 19, whilst second power gate (or select) transistor 14b is turned off. Furthermore, the additional power gate (or select) PMOS transistor 14c is turned off responsive to latch control signal “R=1,”

Therefore controlling the additional power gate transistor 14c responsive to the latch control signal “R”, which is generated in a different voltage domain to S0 on which the value of S1_PG is based, means that, when ramping up from VSYS to VDD0, the additional transistor 14c will be powered off when the first power domain VDD0 is selected (responsive to SEL0=0) thereby preventing any current leakage path which may result from waiting for the PM1 to be turned off responsive to selection control signal S1_PG alone.

Put another way, the stacked power gate (or select) PMOS transistors 14b/14c reduce the risk of an undesirable current path during initial power ramp of VDD0 while VDD1 is powered down.

In embodiments, the third power gate (or select) transistor 14c may be physically larger than the second power gate (or select) transistor 14b, where the larger size provides further reduces the likelihood of the undesirable current path forming (e.g. due to higher resistance provided by the larger transistor).

Whilst FIG. 2 illustratively depicts an implementation of a PMUX module in accordance with the present techniques, and FIGS. 3 to 9 depict systems having additional or alternative components to provide enhancement(s) or improvement(s) over the system of FIG. 2, it will be appreciated that additional or alternative components are not limited to being provided only in the system of a particular figure in which they depicted.

As an illustrative example, the additional power gate transistor depicted in FIG. 9 can be provided in any of the systems depicted in FIGS. 2 to 8. As a further illustrative example, the clamp circuitry described above in relation to FIG. 8 (and as also depicted in FIG. 9) could be provided in any of the systems depicted in FIGS. 2 to 7. As a still further illustrative example, the additional SR latch which is to provide the enable signal described above in relation to FIG. 8 (and as also depicted in FIG. 9) could be provided in any of the systems depicted in FIGS. 2 to 7.

Thus, it will be appreciated that an enhancement(s) or improvement(s) described in relation to any of FIGS. 3-9 could be made to any of the other systems.

The techniques above may also be applied to pmux modules integrated into storage systems.

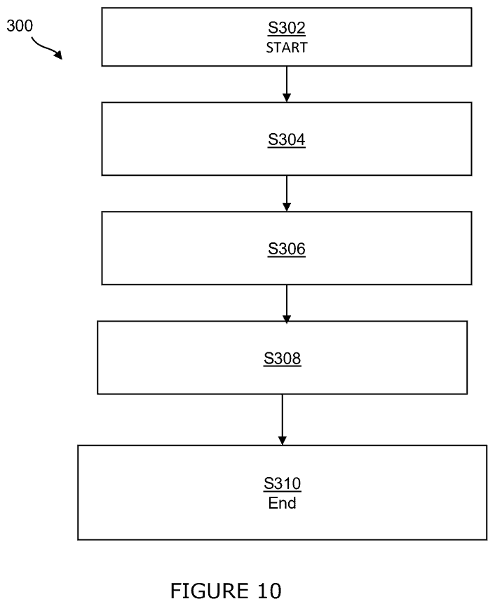

FIG. 10 illustrates a flow diagram of a method 300 for providing a system in accordance with various implementations described herein.

It should be understood that even though method 300 may indicate a particular order of operation execution, in some cases, various certain portions of the operations may be executed in a different order, and on different systems. In other cases, additional operations and/or steps may be added to and/or omitted from method 300.

Also, method 300 may be implemented in hardware and/or software. When implemented in hardware, the method 300 may be implemented with various circuit elements, such as described herein above in reference to FIGS. 2 to 8. When implemented in software, the method 300 may be implemented as a program and/or software instruction process that may be configured for providing selector circuitry design techniques as described herein. Also, when implemented in software, instructions related to implementing the method 300 may be stored in memory and/or a database. For instance, a computer or various other types of computing devices having a processor and memory may be configured to perform method 300.

As described and shown in reference to FIG. 10, method 300 may be utilized for fabricating and/or manufacturing, or causing to be fabricated and/or manufactured, an integrated circuit (IC) that implements a system comprising PMUX circuitry and techniques as described herein that are related to providing PMUX circuitry and/or various associated systems, devices, components, circuits and related architecture.

At S302, method 300 starts.

At S304, method 300 may provide interface circuitry comprising an SR latch to receive selection signals and generate first and second interface control signals in response thereto.

At S306, method 300 may provide a power output circuit comprising a first transistor arranged to provide a first voltage to a PMUX output and a second transistor arranged to provide a second voltage to the PMUX output.

At S308, the method may provide PMUX control circuit to provide a first control signal to control the first transistor of the power output circuit and to provide a second control signal to control the second transistor of the power output circuit, where the first and second control signals from the PMUX control circuit are generated responsive to the interface control signals.

At S310, method 300 ENDS.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software and hardware. Where the word “component” is used, it will be understood by one of ordinary skill in the art to refer to any portion of any of the above embodiments.

The present techniques described herein may be operational with numerous general purpose or special purpose computing system environments or configurations. Examples of computing systems, environments, and/or configurations that may be suitable for use with the various technologies described herein include, but are not limited to, personal computers, server computers, hand-held or laptop devices, multiprocessor systems, microprocessor-based systems, set top boxes, programmable consumer electronics, network PCs, minicomputers, mainframe computers, smart phones, tablets, wearable computers, cloud computing systems, virtual computers, marine electronics devices, and the like.

The present techniques described herein may be implemented in distributed computing environments where tasks are performed by remote processing devices that are linked through a communications network, e.g., by hardwired links, wireless links, or various combinations thereof. In a distributed computing environment, program modules may be located in both local and remote computer storage media including, for example, memory storage devices and similar.

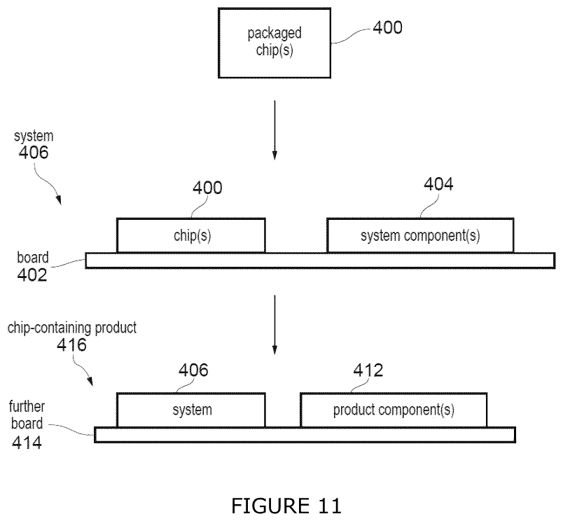

As an illustrative example, as shown in FIG. 11, one or more packaged chips 400, with the circuitry described above implemented on one chip or distributed over two or more of the chips, may be manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1. Power multiplexer circuitry comprising:
interface control logic comprising:
first SR latch circuitry to generate first and second interface control signals responsive to first and second latch control signals;
a PMUX control circuit to provide a first selection control signal responsive to the first interface control signal and to provide a second selection control signal responsive to the second interface control signal;
a power output circuit to output a selected voltage at a PMUX output, the power output circuit comprising:
first switch circuitry arranged between a first voltage rail and the PMUX output to provide an electrical path therebetween responsive to the first selection control signal;
second switch circuitry arranged between a second voltage rail and the PMUX output to provide an electrical path therebetween responsive to the second selection control signal.

2. The circuitry of claim 1, where the interface control logic comprises first interface switch circuitry arranged between the first voltage rail and an interface output node to provide an electrical path therebetween responsive to the first interface control signal.

3. The circuitry of claim 2, where the first interface switch circuitry comprises a first interface transistor arranged between the first voltage rail and the interface output node to provide the electrical path therebetween.

4. The circuitry of claim 3, where the interface control logic comprises second interface switch circuitry arranged between the second voltage rail and the interface output node to provide an electrical path therebetween responsive to the second interface control signal.

5. The circuitry of claim 4, where the second interface switch circuitry comprises a second interface transistor arranged between the second voltage rail and the interface output node to provide the electrical path therebetween.

6. The circuitry of claim 5, where the second interface switch circuitry comprises a third interface transistor arranged in series with the second interface transistor between second voltage rail and the interface output node to provide the electrical path therebetween, where the third interface transistor is controllable responsive to a first latch control signal.

7. The circuitry of claim 4, where the voltage at the interface output node is to power the first SR latch circuitry.

8. The circuitry of claim 7, where the interface circuitry is electrically isolated from the PMUX control circuit.

9. The circuitry of claim 8, where the electrical isolation is provided by a physical separation or insulative material.

10. The circuitry of claim 1, where the PMUX control circuit comprises:
a first logic gate to provide the first selection control signal responsive to the first latch control signal and an enable signal; and
a second logic gate to provide the second selection control signal responsive to the second latch control signal and the enable signal.

11. The circuitry of claim 10, where the PMUX control circuit comprises a level shifter to level shift an external signal to provide the enable signal at a voltage level of the selected voltage.

12. The circuitry of claim 10, where the PMUX control circuit comprises second SR latch circuitry to provide the enable signal.

13. The circuitry of claim 10, where the PMUX control circuit comprises clamp circuitry, where the output of the clamp circuitry is to supply the PMUX control circuit and power output circuit with the selected voltage.

14. The circuitry of claim 1, where the circuitry is integrated in the storage system.

15. The circuitry of claim 1, where the first voltage rail is electrically isolated from the second voltage rail.

16. The circuitry of claim 1, where first switch circuitry comprises a first select transistor arranged between the first voltage rail and the PMUX output to provide the electrical path therebetween and where the second switch circuitry comprises a second select transistor arranged between the second voltage rail and the PMUX output to provide the electrical path therebetween.

17. The circuitry of claim 16, where the second switch circuitry comprises a third select transistor arranged in series with the second select transistor between the second voltage rail and the PMUX output to provide the electrical path therebetween, where the third select transistor is controllable responsive to the first latch control signal.

18. A system comprising power multiplexer circuitry comprising:
interface control logic comprising:
SR latch circuitry to generate first and second interface control signals responsive to first and second latch control signals;
a PMUX control circuit to provide a first selection control signal responsive to the first interface control signal and to provide a second selection control signal responsive to the second interface control signal;
a power output circuit to output a selected voltage at a PMUX output, the power output circuit comprising:
first switch circuitry arranged between a first voltage rail and the PMUX output to provide an electrical path therebetween responsive to the first selection control signal;
second switch circuitry arranged between a second voltage rail and the PMUX output to provide an electrical path therebetween responsive to the second selection control signal.

19. The system of claim 18 comprising a storage system, the storage system comprising cell circuitry arranged in electrical communication with the PMUX output.

20. The system of claim 18 comprising an electrical discharge clamp on an electrical path between the PMUX output and the cell circuitry.
